(19) United States
(12) Patent Application Publication
(10) Pub. No.: US 2025/0299981 A1
(43) Pub. Date: Sep. 25, 2025

(54) SYSTEM AND METHOD FOR ADJUSTING ETCH SELECTIVITY OF ETCHANT SOLUTION

(71) Applicant: Tokyo Electron Limited, Tokyo (JP)

(72) Inventors: Ronald Nasman, Albany, NY (US); Peter D'Elia, Albany, NY (US)

(21) Appl. No.: 18/610,909

(22) Filed: Mar. 20, 2024

(51) Int. Cl. H01L 21/67; H01L 21/306; H01L 21/66

(52) U.S. Cl. CPC H01L 21/67086; H01L 21/30604; H01L 21/67253; H01L 22/10

(57) ABSTRACT

An apparatus includes a first holding tank holding first nanoparticles, a second holding tank holding second nanoparticles, a third holding tank holding water, a fourth holding tank holding an acid, and a first mixing tank operably coupled to the first holding tank, the second holding tank, and the third holding tank. First mixing tank mixes and holds a nanoparticle-water mixture of portions of the water, the first nanoparticles, and the second nanoparticles. Apparatus further includes a second mixing tank operably coupled to the first mixing tank and the fourth holding tank, an etch bath operably coupled to the second mixing tank, and a sensor operably coupled to the etch bath. Second mixing tank mixes and holds an etchant solution including a mixture of a portion of the acid and the nanoparticle-water mixture. Etch bath holds the etchant solution. Sensor monitors an etch selectivity of the etchant solution.

### TECHNICAL FIELD

The present disclosure relates generally to systems and methods for processing a substrate and, in particular embodiments, to a system and method for adjusting an etch selectivity of an etchant solution.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

The patenting process may include soaking the semiconductor substrate into an etchant solution of a desired etch selectivity. Maintaining the desired etch selectivity of the etchant solution ensures consistent processing of semiconductor substrates.

### SUMMARY

In accordance with an embodiment of the present disclosure, an apparatus includes a first holding tank holding first nanoparticles, a second holding tank holding second nanoparticles, a third holding tank holding water, and a fourth holding tank holding an acid. The apparatus further includes a first mixing tank operably coupled to the first holding tank, the second holding tank, and the third holding tank. The first mixing tank mixes and holds a nanoparticle-water mixture of a portion of the water, a portion of the first nanoparticles, and a portion of the second nanoparticles. The apparatus further includes a second mixing tank operably coupled to the first mixing tank and the fourth holding tank. The second mixing tank mixes and holds an etchant solution including a mixture of a portion of the acid and the nanoparticle-water mixture. The apparatus further includes an etch bath operably coupled to the second mixing tank. The etch bath holds the etchant solution. The apparatus further includes a sensor operably coupled to the etch bath. The sensor monitors an etch selectivity of the etchant solution.

In accordance with an embodiment of the present disclosure, a method includes adding first nanoparticles and second nanoparticles to water to form a nanoparticle-water mixture, agitating the nanoparticle-water mixture, adding the nanoparticle-water mixture to an acid to from an etchant solution, soaking a first wafer into the etchant solution, and monitoring an etch selectivity of the etchant solution. The method further includes, in response to determining that the etch selectivity of the etchant solution is outside a desired etch selectivity range, recycling at least a portion of the etchant solution.

In accordance with an embodiment of the present disclosure, a method includes adding silicon oxide nanoparticles and silicon nitride nanoparticles to water to form a nanoparticle-water mixture, agitating the nanoparticle-water mixture to maintain the silicon oxide nanoparticles and the silicon nitride nanoparticles in a state of suspension within the nanoparticle-water mixture, adding the nanoparticle-water mixture to phosphoric acid to from an etchant solution, and soaking a first wafer into the etchant solution. The first wafer includes one or more silicon oxide features and one or more silicon nitride features. The method further includes monitoring an etch selectivity of the etchant solution and, in response to determining that the etch selectivity of the etchant solution is outside a desired etch selectivity range, recycling at least a portion of the etchant solution.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a schematic view of an etch apparatus in accordance with various embodiments;

FIG. 2 is a schematic view of an etch apparatus in accordance with various embodiments;

FIG. 3 is a schematic view of a controller in accordance with various embodiments;

FIG. 4A-4C illustrate perspective and cross-sectional views of different stages of manufacturing a patterned mask over a wafer in accordance with various embodiments;

FIGS. 5A-5E illustrate a flow diagram of a method for operating an etch apparatus in accordance with various embodiments; and

FIGS. 6A-6E illustrate a flow diagram of a method for operating an etch apparatus in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Generally, when an etchant solution comprising an acid such as hot phosphoric acid (H₃PO₄) is used to selectively etch silicon nitride (Si₃N₄) relative to silicon oxide (SiO₂), the etchant solution goes through a preconditioning step. During the preconditioning step dummy silicon wafer are soaked into the etchant solution to attain a desired etch selectivity of the etchant solution. The preconditioning step reduces efficiency of the selective etch process.

The selective etch process of the present disclosure allows for eliminating the preconditioning step to adjust the etch selectivity of the etchant solution. Instead, the etch selectivity of the etchant solution is adjusted by adding a nanoparticle-water mixture to the acid (e.g., phosphoric acid). The nanoparticle-water mixture may comprise Si₃N₄ and SiO₂ nanoparticles suspended in water. Amounts of acid, water and nanoparticles may be determined such that the resulting etchant solution has a desired etch selectivity. In some embodiments, the etch selectivity of the etchant solution may be monitored during the selective etch process and may be adjusted if the etch selectivity is not within a desired etch selectivity range. The selective etch process may be integrated into single wafer processing or batch wafer processing.

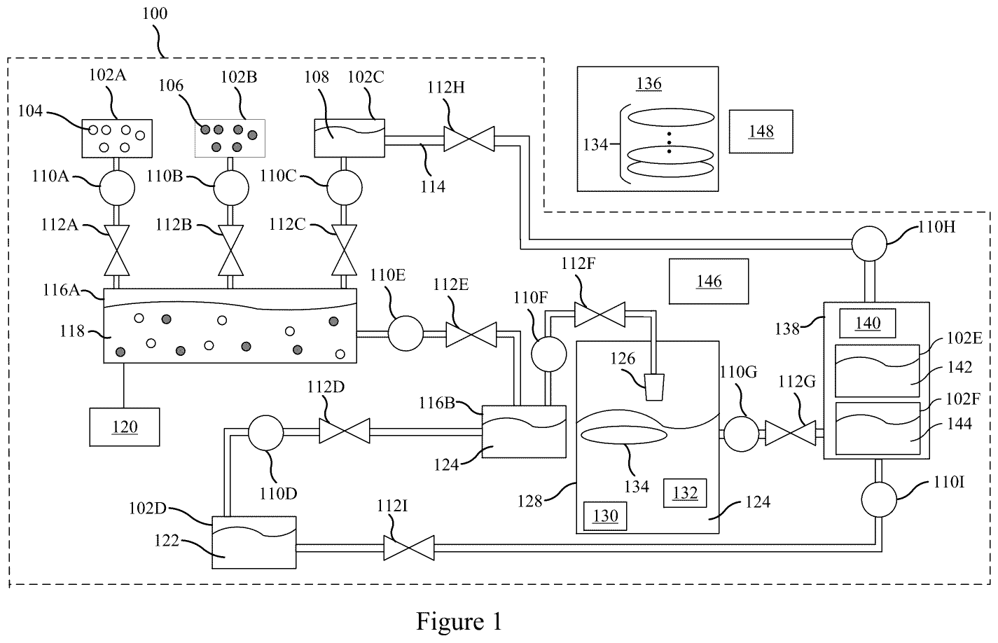

FIG. 1 is a schematic view of an etch apparatus 100 in accordance with various embodiments. In some embodiments, the etch apparatus 100 comprises holding tanks 102A, 102B, and 102C that are coupled to a mixing tank 116A, and a holding tank 102D that is coupled to a mixing tank 116B. The mixing tank 116A may be coupled to the mixing tank 116B. The holding tank 102A is configured to hold nanoparticles 104. The nanoparticles 104 may comprise silicon nitride (Si₃N₄). The nanoparticles 104 may have a diameter in a range from 10 nm to 500 nm. The holding tank 102B is configured to hold nanoparticles 106. The nanoparticles 104 and 106 may comprise different materials. For example, the nanoparticles 106 may comprise silicon oxide (SiO₂). The nanoparticles 106 may have a diameter in a range from 10 nm to 500 nm. The holding tank 102C is configured to hold de-ionized (DI) water (H₂O) 108. In the following DI water may be also referred to as water. The holding tank 102D is configured to hold an acid 122. In some embodiments, the acid 122 comprises phosphoric acid (H₃PO₄).

In some embodiments, the holding tank 102A may be coupled to the mixing tank 116A through a valve 112A and a pump 110A. In such embodiments, the holding tank 102A may hold the nanoparticles 104 in the form of a mixture, such as a nanoparticle-water mixture. In some embodiments, the holding tank 102B may be coupled to the mixing tank 116A through a valve 112B and a pump 110B. In such embodiments, the holding tank 102B may hold the nanoparticles 106 in the form of a mixture, such as a nanoparticle-water mixture. In some embodiments, the holding tank 102C may be coupled to the mixing tank 116A through a valve 112C and a pump 110C. In some embodiments, the holding tank 102D may be coupled to the mixing tank 116B through a valve 112D and a pump 110D. In some embodiments, the mixing tank 116A may be coupled to the mixing tank 116B through a valve 112E and a pump 110E.

The valves 112A-112E may be configured to control flows of fluids. Each of the valves 112A-112E may comprise a check valve, a flow control valve, or any suitable valve. The valves 112A-112E may be electronically controlled valves that may be opened or closed in response to receiving signals from a controller 146. The pumps 110A-110E are configured to move or pump fluids, for example, by mechanical action. Each of the pumps 110A-110E may comprise a positive-displacement pump such as a rotary-type positive-displacement pump, a reciprocating-type positive-displacement pump, a linear-type positive-displacement pump, or the like. The pumps 110A-110E may be electronically controlled pumps that may be turned ON or OFF in response to receiving signals from the controller 146.

In some embodiments, the mixing tank 116A is configured to receive the nanoparticles 104 from the holding tank 102A using the pump 110A and the valve 112A, the nanoparticles 106 from the holding tank 102B using the pump 110B and the valve 112B, and the water 108 from the holding tank 102C using the pump 110C and the valve 112C. The mixing tank 116A is further configured to mix the received fluids to form a nanoparticle-water mixture 118 and hold the nanoparticle-water mixture 118. The mixing tank 116A may be coupled to an agitator 120. The agitator 120 is configured to agitate the nanoparticle-water mixture 118 to maintain the nanoparticles 104 and 106 in a suspended state within the nanoparticle-water mixture 118. The agitator 120 may comprise an ultrasonic agitator, a megasonic agitator, a mechanical mixer, or the like.

In some embodiments, the mixing tank 116B is configured to receive the nanoparticle-water mixture 118 from the mixing tank 116A using the pump 110E and the valve 112E, and the acid 122 from the holding tank 102D using the pump 110D and the valve 112D. The mixing tank 116B is further configured to mix the received fluids to form an etchant solution 124 and hold the etchant solution 124. In some embodiments, the nanoparticles 104 and 106 in the nanoparticle-water mixture 118 dissolve in the acid 122 to form the etchant solution 124. As described below in greater detail, an amount of the nanoparticles 104, an amount of the nanoparticles 106, an amount of the water 108, and an amount of the acid 122 received by the mixing tank 116B may be controlled to control an etch selectivity of the etchant solution 124. In some embodiments when the acid 122 comprises phosphoric acid, the etchant solution 124 is configured to selectively etch silicon nitride and have the etch selectivity (i.e., a ratio of an etch rate of silicon nitride to an etch rate of silicon oxide) of 80:1 or greater.

In some embodiments, the etch apparatus 100 further comprises an etch bath 128 that is coupled to the mixing tank 116B through a valve 112F and a pump 110F. The valve 112F may be configured to control a flow of a fluid (e.g., the etchant solution 124). The valve 112F may comprise a check valve, a flow control valve, or any suitable valve. The valve 112F may be an electronically controlled valve that may be opened or closed in response to receiving signals from the controller 146. The pump 110F is configured to move or pump a fluid (e.g., the etchant solution 124), for example, by mechanical action. The pump 110F may comprise a positive-displacement pump such as a rotary-type positive-displacement pump, a reciprocating-type positive-displacement pump, a linear-type positive-displacement pump, or the like. The pump 110F may be an electronically controlled pump that may be turned ON or OFF in response to receiving signals from the controller 146.

The etch bath 128 is configured to receive the etchant solution 124 from the mixing tank 116B through a nozzle 126 and hold the etchant solution 124 during processing. The etch bath 128 may comprise a heating element 130 that is configured to heat the etchant solution 124 to a desired process temperature. In some embodiments, the process temperature may be in a range from 100° C. to 165° C. The heating element 130 may be a resistive heating element, a hot plate, an infrared lamp, or the like. The etch bath 128 may further comprise a sensor 132 that is configured to measure the etch selectivity of the etchant solution 124. The sensor 132 may comprise a PH sensor, a conductivity sensor, a chemical concentration sensor, or the like.

In some embodiments, the etch apparatus 100 further comprises a recycling system 138 that is coupled to the etch bath 128 through a valve 112G and a pump 110G. The recycling system 138 is further coupled to the holding tank 102C through a valve 112H and a pump 110H, and the holding tank 102D through a valve 112I and a pump 110I. The valves 112G-112I may be configured to control flows of fluids. Each of the valves 112G-112I may comprise a check valve, a flow control valve, or any suitable valve. The valves 112G-112I may be electronically controlled valves that may be opened or closed in response to receiving signals from the controller 146. The pumps 110G-110I are configured to move or pump fluids, for example, by mechanical action. Each of the pumps 110G-110I may comprise a positive-displacement pump such as a rotary-type positive-displacement pump, a reciprocating-type positive-displacement pump, a linear-type positive-displacement pump, or the like. The pumps 110G-110I may be electronically controlled pumps that may be turned ON or OFF in response to receiving signals from the controller 146.

The recycling system 138 may comprise one or more filters 140 and holding tanks 102E and 102F. The recycling system 138 is configured to receive the etchant solution 124 from the etch bath 128 and pass the etchant solution 124 through the one or more filters 140 to remove undissolved nanoparticles 104 and/or undissolved nanoparticles 106 from the etchant solution 124. In some embodiments, the one or more filters 140 may comprise a first filter configured to remove the undissolved nanoparticles 104 from the etchant solution 124 and a second filter configured to remove the undissolved nanoparticles 106 from the etchant solution 124. In some embodiments, the remove undissolved nanoparticles 104 and/or the undissolved nanoparticles 106 may be recovered from the filter and transferred to the holding tanks 102A and/or 102B, respectively. The recycling system 138 is configured to recover water 142 and an acid 144 from the etchant solution 124 and hold the recovered water 142 in the holding tank 102E and the recovered acid 144 in the holding tank 102F. The recycling system 138 is further configured to transfer the recovered water 142 from the holding tank 102E to the holding tank 102C and the recovered acid 144 from the holding tank 102F to the holding tank 102D.

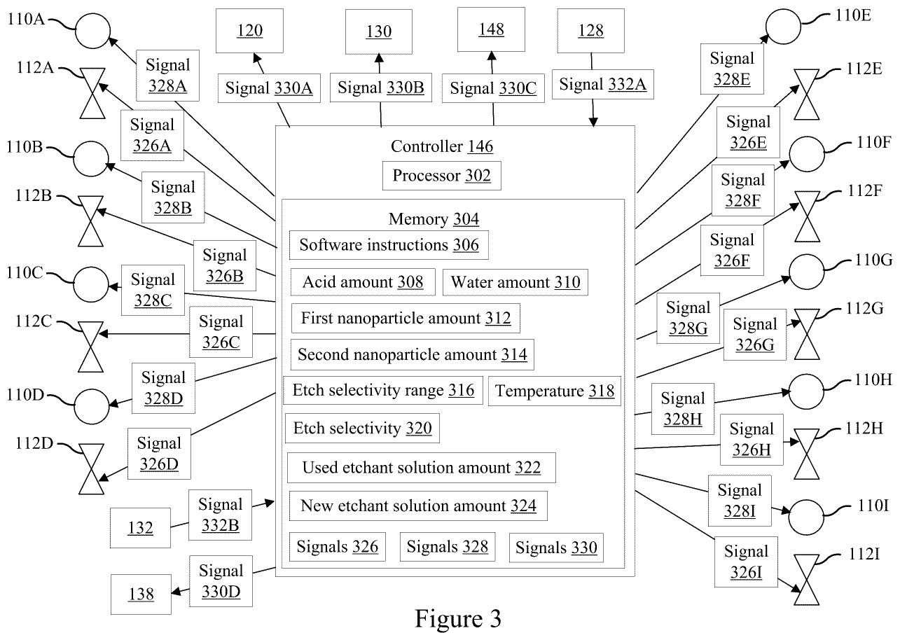

The etch apparatus 100 may further comprise a plurality of conduits 114 that couple various components of the etch apparatus 100 to one another. The plurality of conduits 114 may comprise pipes that are configured to transfer various fluids between the components of the etch apparatus 100. In some embodiments, the etch apparatus 100 further comprises the controller 146. The controller 146 is configured to send signals to various components of the etch apparatus 100 to control the operation the etch apparatus 100. The controller 146 and its operation is described in greater detail below with reference to FIG. 3.

In some embodiments, the etch apparatus 100 may be coupled to a loadlock chamber 136 and a transfer mechanism 148. The loadlock chamber 136 may be configured to receive one or more wafers 134 for further processing. The transfer mechanism 148 may be configured to transfer the one or more wafers 134 from the loadlock chamber 136 to the etch bath 128. The transferred wafer 134 is soaked or submerged into the etchant solution 124 for processing. The transfer mechanism 148 may comprise a robotic arm, or any transfer mechanism that is suable for transferring wafers.

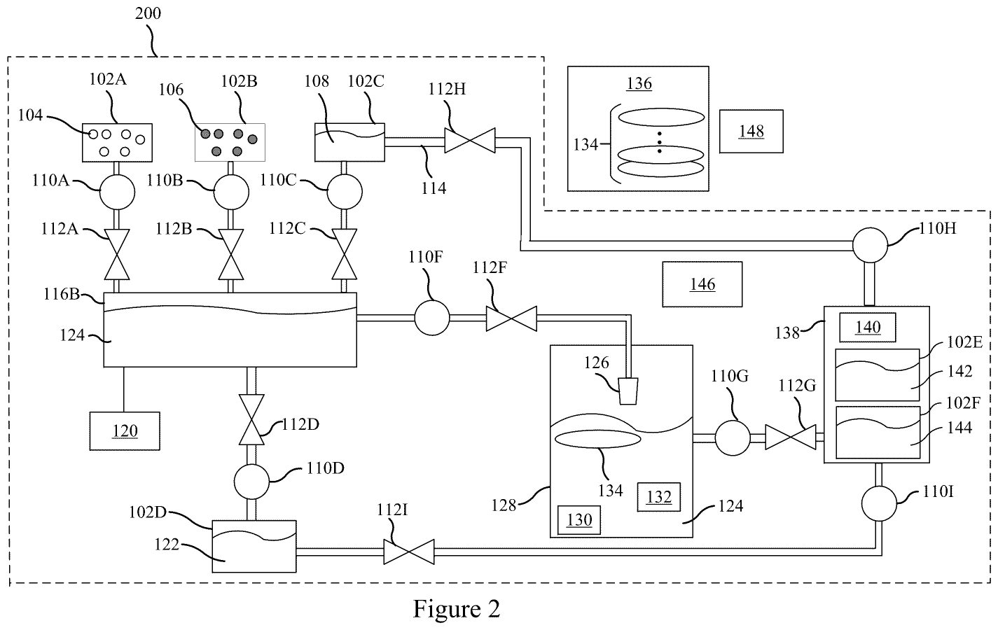

FIG. 2 is a schematic view of an etch apparatus 200 in accordance with various embodiments. The etch apparatus 200 is similar to the etch apparatus 100 (see FIG. 1), with similar features being labeled using similar numerical references, and descriptions of the similar features are not repeated herein. In the etch apparatus 200, the mixing tank 116A, the pump 110E, and the valve are omitted such that the holding tanks 102A, 102B, and 102C are directly coupled to the second mixing tank 116B.

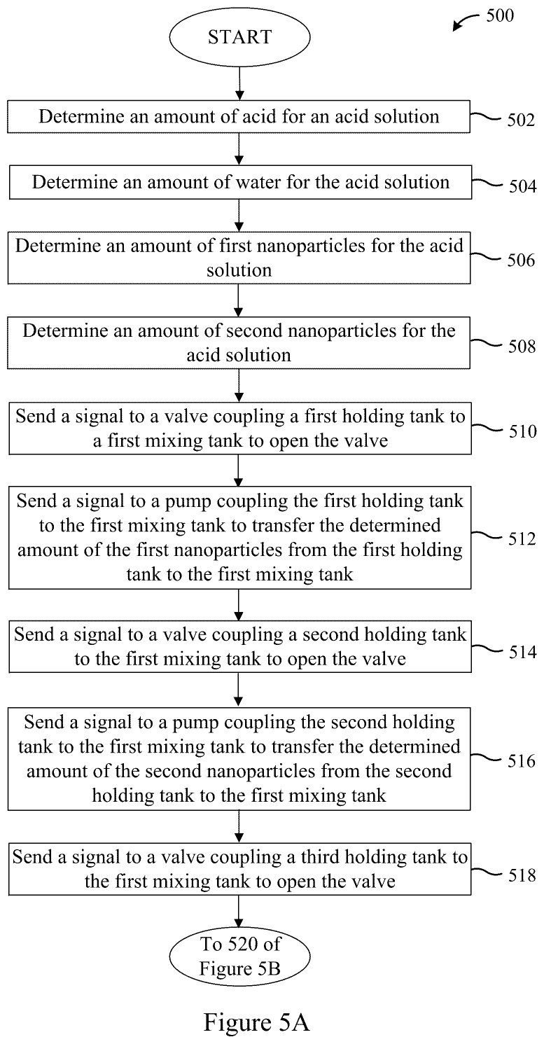

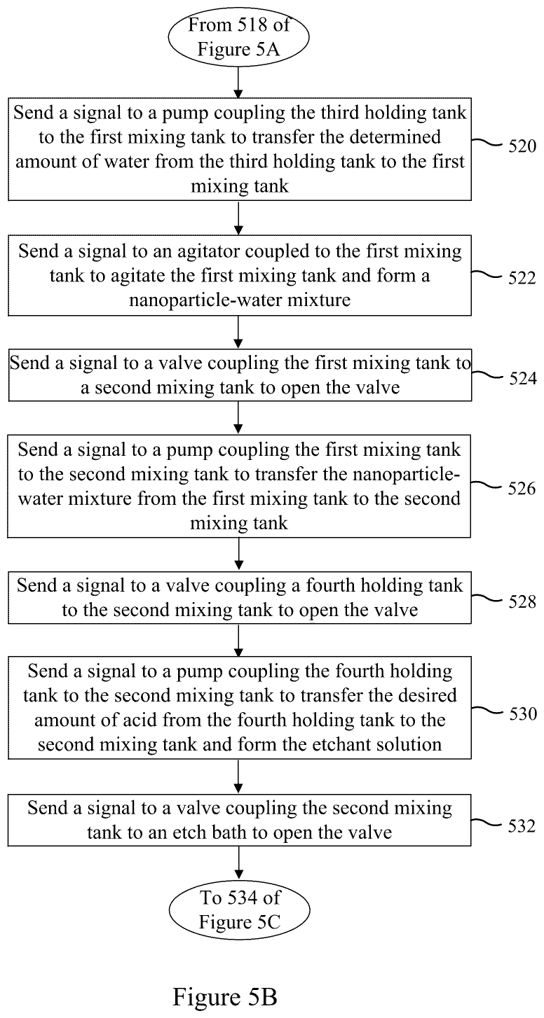

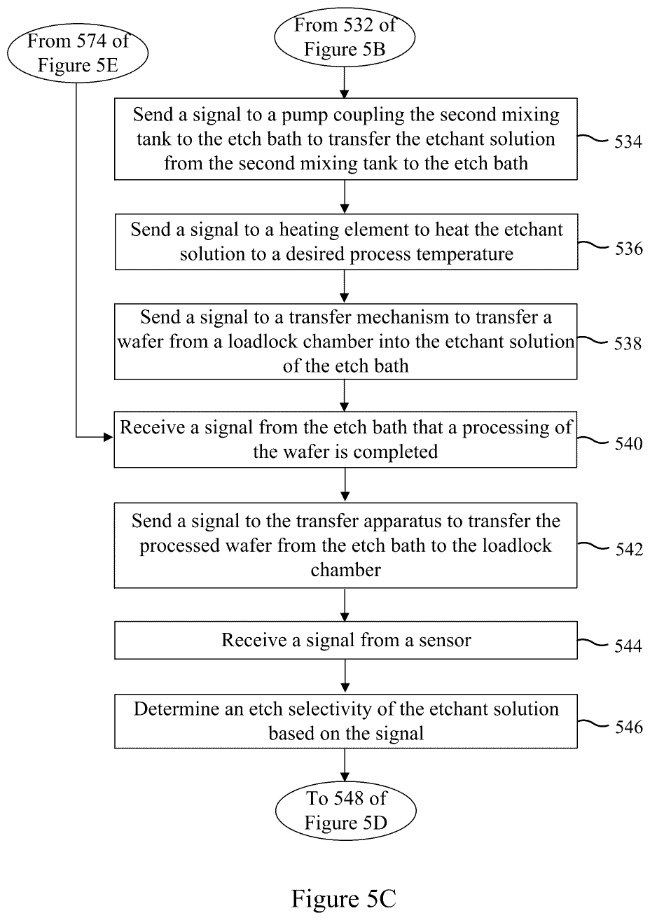

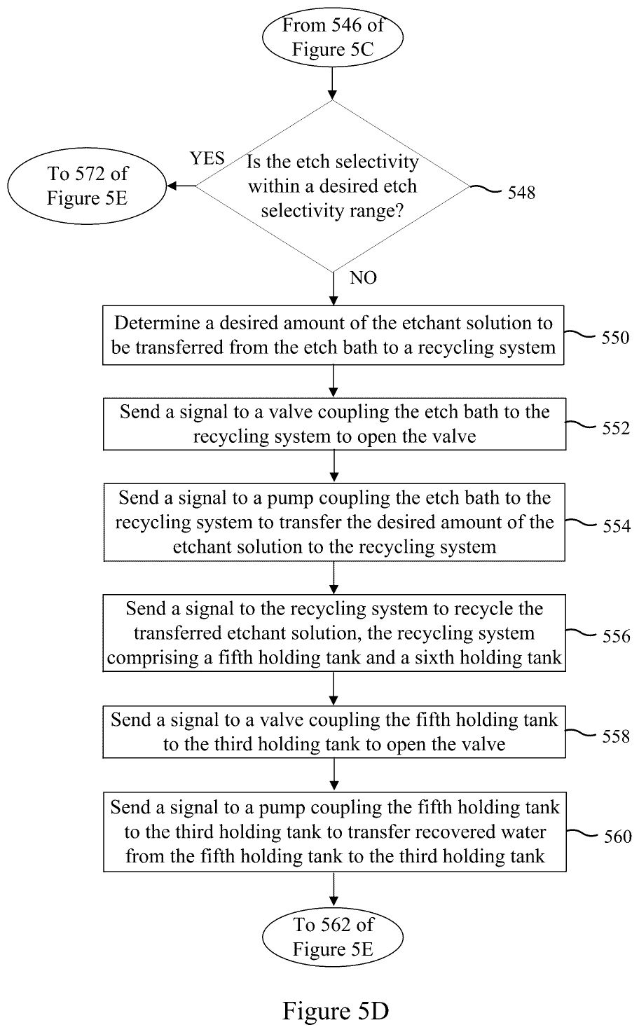

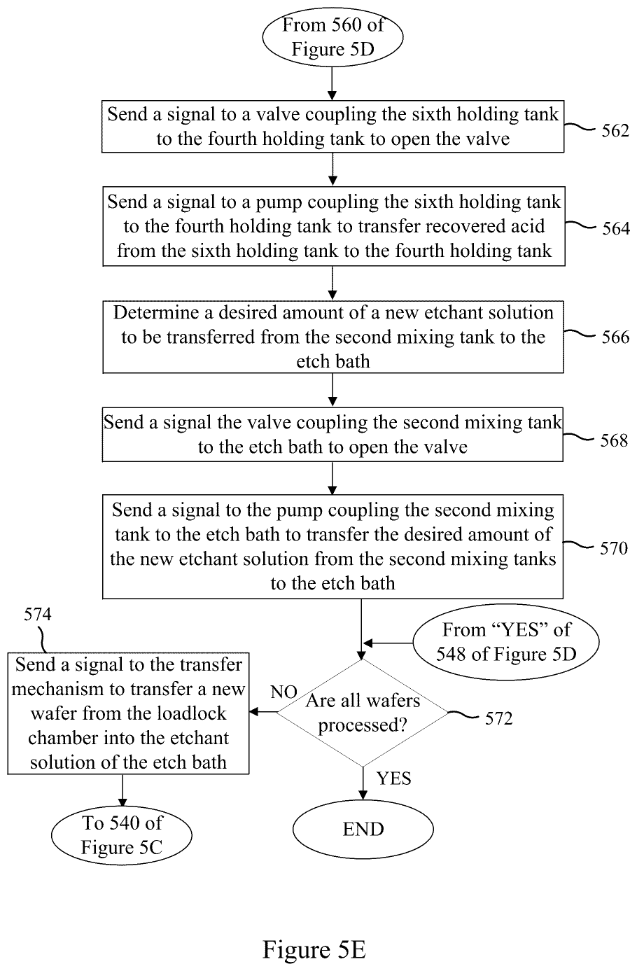

FIG. 3 is a schematic view of the controller 146 in accordance with various embodiments. The controller 146 is configured to control operations of an etch apparatus (e.g., etch apparatus 100 of FIG. 1 or etch apparatus 200 of FIG. 2) by controlling operations of various components of the etch apparatus. The controller 146 may comprise a processor 302 communicatively coupled to a memory 304. The processor 302 may comprise one or more microprocessors. The memory 304 may comprise a non-transitory computer-readable medium that is configured to store software instructions 306 and/or any other data. The software instructions 306, when executed by the processor 302, cause the processor 302 to perform various functions of the controller 146 described herein. In some embodiments, the processor 302 of the controller 146 may generate signals 326, 328, and 330 that are transmitted to various components of the etch apparatus. The processor 302 of the controller 146 may be configured to receive signals 332 from various components of the etch apparatus. In some embodiments, the etch apparatus may be operated according to a method 500 descried below with reference to FIG. 5.

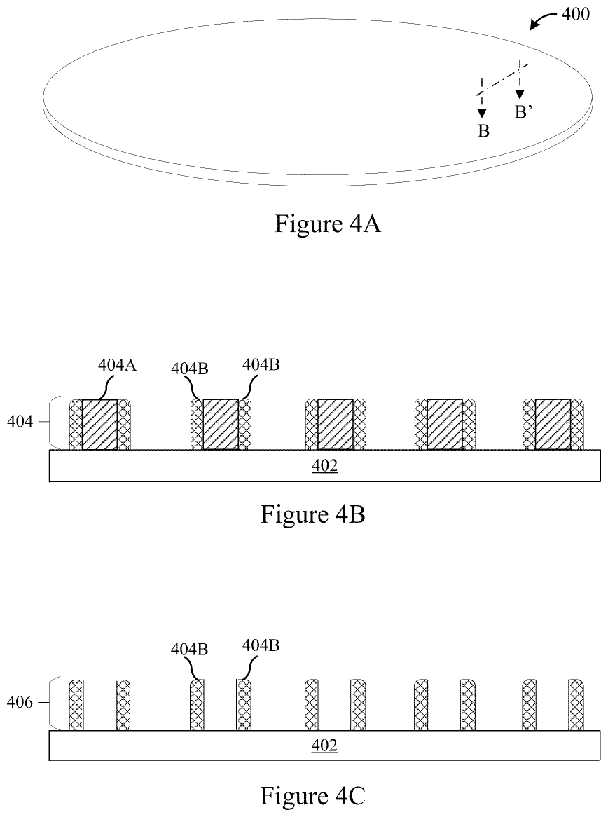

FIG. 4A-4C illustrate perspective and cross-sectional views of different stages of manufacturing a patterned mask 406 over a wafer 400 in accordance with various embodiments. In particular, FIG. 4A illustrates a perspective view and FIGS. 4B and 4C illustrate cross-sectional views along a line BB′ shown in FIG. 4A. Referring first to FIGS. 4A and 4B, the wafer 400 may comprise a substrate 402. The substrate 402 may include semiconductor devices or semiconductor structures and may be formed in any suitable manner, including using any suitable combination of wet and/or dry deposition and etch techniques. In such embodiments, the substrate 402 may include isolation regions such as shallow trench isolation (STI) regions, diffusion regions, as well as other regions formed therein.

The substrate 402 may comprise layers of semiconductors suitable for various microelectronics. In one or more embodiments, the substrate 402 may be a silicon wafer, or a silicon-on-insulator (SOI) wafer. In certain embodiments, the substrate 402 may comprise a silicon germanium wafer, silicon carbide wafer, gallium arsenide wafer, gallium nitride wafer, or other compound semiconductors. In other embodiments, the substrate 402 may comprise heterogeneous layers such as silicon germanium on silicon, gallium nitride on silicon, silicon carbon on silicon, or layers of silicon on a silicon or SOI substrate.

In some embodiments, a patterned structure 404 is formed over the substrate 402. The patterned structure 404 may comprise a plurality of mandrels 404A and a plurality of spacers 404B formed on sidewalls of the plurality of mandrels 404A. The mandrels 404A may be formed by depositing a first dielectric material over the substrate 402 and patterning the first dielectric material using suitable photolithography and etch methods. In the illustrated embodiment, the first dielectric material of the plurality of mandrels 404A comprises silicon nitride (Si₃N₄). The plurality of spacers 404B may be formed by blanket depositing a second dielectric material different from the first dielectric material over the plurality of mandrels 404A using, for example, a chemical vapor deposition (CVD) process, an atomic layer deposition (ALD) process, plasma deposition processes (e.g., a plasma-enhanced CVD (PECVD) process), and/or other layer deposition processes or combinations of processes. The second dielectric material is then etched using, for example, a reactive-ion etch (RIE) process to remove horizontal (or lateral) portions of the second dielectric material. In the illustrated embodiment, the second dielectric material of the plurality of spacers 404B comprises silicon oxide (SiO₂).

In FIG. 4C, the plurality of mandrels 404A (see FIG. 4B) are selectively removed such that the plurality of spacers 404B form a patterned mask 406. The patterned mask 406 may be used as an etch mask while etching a desired layer of the substrate 402. In some embodiments when the plurality of mandrels 404A comprise silicon nitride and the plurality of spacers 404B comprise silicon oxide, the plurality of mandrels 404A may be selectively removed using the etch apparatus 100 (see FIG. 1) or the etch apparatus 200 (see FIG. 2). In some embodiments, the selective removal process may be performed according to a method 500 descried below with reference to FIG. 5.

FIGS. 5A-5E illustrate a flow diagram of a method 500 for operating the etch apparatus 100 (see FIG. 1) in accordance with various embodiments. In some embodiments, operations of the etch apparatus 100 may be controlled by the controller 146 (see FIGS. 1 and 3).

Method 500 starts with operation 502. At operation 502, a processor 302 of the controller 146 determines an amount 308 of an acid 122 for an etchant solution 124. At operation 504, the processor 302 of the controller 146 determines an amount 310 of water 108 for the etchant solution 124. At operation 506, the processor 302 of the controller 146 determines an amount 312 of first nanoparticles 104 for the etchant solution 124. At operation 508, the processor 302 of the controller 146 determines an amount 314 of second nanoparticles 106 for the etchant solution 124. In some embodiments, the amount 308 of the acid 122, the amount 310 of the water 108, the amount 312 of the first nanoparticles 104, and the amount 314 of the second nanoparticles 106 may be determined such that the etchant solution 124 has a desired etch selectivity. In some embodiments when the acid 122 comprises phosphoric acid, the etchant solution 124 is configured to selectively etch silicon nitride and have the etch selectivity (i.e., a ratio of an etch rate of silicon nitride to an etch rate of silicon oxide) of 80:1 or greater.

At operation 510, the processor 302 of the controller 146 sends a signal 326A to a valve 112A coupling a first holding tank 102A to a first mixing tank 116A to open the valve 112A. At operation 512, the processor 302 of the controller 146 sends a signal 328A to a pump 110A coupling the first holding tank 102A to the first mixing tank 116A to transfer the determined amount 312 of the first nanoparticles 104 from the first holding tank 102A to the first mixing tank 116A. At operation 514, the processor 302 of the controller 146 sends a signal 326B to a valve 112B coupling a second holding tank 102B to the first mixing tank 116A to open the valve 112B. At operation 516, the processor 302 of the controller 146 sends a signal 328B to a pump 110B coupling the second holding tank 102B to the first mixing tank 116A to transfer the determined amount 314 of the second nanoparticles 106 from the second holding tank 102B to the first mixing tank 116A.

At operation 518, the processor 302 of the controller 146 sends a signal 326C to a valve 112C coupling a third holding tank 102C to the first mixing tank 116A to open the valve 112C. At operation 520, the processor 302 of the controller 146 sends a signal 328C to a pump 110C coupling the third holding tank 102C to the first mixing tank 116A to transfer the determined amount 310 of water 108 from the third holding tank 102C to the first mixing tank 116A.

At operation 522, the processor 302 of the controller 146 sends a signal 330A to an agitator 120 coupled to the first mixing tank 116A to agitate the first mixing tank 116A and form a nanoparticle-water mixture 118. At operation 524, the processor 302 of the controller 146 sends a signal 326E to a valve 112E coupling the first mixing tank 116A to a second mixing tank 116B to open the valve 112E. At operation 526, the processor 302 of the controller 146 sends a signal 328E to a pump 110E coupling the first mixing tank 116A to the second mixing tank 116B to transfer the nanoparticle-water mixture 118 from the first mixing tank 116A to the second mixing tank 116B.

At operation 528, the processor 302 of the controller 146 sends a signal 326D to a valve 112D coupling a fourth holding tank 102D to the second mixing tank 116B to open the valve 112D. At operation 530, the processor 302 of the controller 146 sends a signal 328D to a pump 110D coupling the fourth holding tank 102D to the second mixing tank 116B to transfer the desired amount 308 of the acid 122 from the fourth holding tank 102D to the second mixing tank 116B and form the etchant solution 124.

At operation 532, the processor 302 of the controller 146 sends a signal 326F to a valve 112F coupling the second mixing tank 116 to an etch bath 128 to open the valve 112F. At operation 534, the processor 302 of the controller 146 sends a signal 328F to a pump 110F coupling the second mixing tank 116B to the etch bath 128 to transfer the etchant solution 124 from the second mixing tank 116B to the etch bath 128. In some embodiments, the etchant solution 124 may be transferred into the etch bath 128 using a nozzle 126. In some embodiments, a portion or all of the etchant solution 124 that is held in the second mixing tank 116 may be transferred to the etch bath 128.

At operation 536, the processor 302 of the controller 146 sends a signal 330B to a heating element 130 to heat the etchant solution 124 to a desired process temperature 318. In some embodiments, the process temperature 318 may be in a range from 100° C. to 165° C. At operation 538, the processor 302 of the controller 146 sends a signal 330C to a transfer mechanism 148 to transfer a wafer 134 from a loadlock chamber 136 into the etchant solution 124 of the etch bath 128.

At operation 540, the processor 302 of the controller 146 receives a signal 332A from the etch bath 128 that a processing of the wafer 134 is completed. At operation 542, the processor 302 of the controller 146 sends a signal 330C to the transfer mechanism 148 to transfer the processed wafer 134 from the etch bath 128 to the loadlock chamber 136. At operation 544, the processor 302 of the controller 146 receives a signal 332B from a sensor 132. At operation 546, the processor 302 of the controller 146 determines an etch selectivity 320 of the etchant solution 124 based on the signal 332B. In some embodiments, etch byproducts may affect the etch selectivity 320 of the etchant solution 124 such that the etch selectivity 320 of the etchant solution 124 within the etch bath 128 is deferent from an etch selectivity of the etchant solution 124 while in the second mixing tank 116B.

At operation 548, the processor 302 of the controller 146 determines whether the etch selectivity 320 of the etchant solution 124 is within a desired etch selectivity range 316. In some embodiments, the etch selectivity range 316 may be of 80:1 or greater. In response to determining at operation 548 that the etch selectivity 320 is not within the desired etch selectivity range 316, method 500 proceeds to operation 550. At operation 550, the processor 302 of the controller 146 determines a desired amount 322 of the etchant solution 124 to be transferred from the etch bath 128 to a recycling system 138. The recycling system 138 may comprise one or more filters 140, a fifth holding tank 102E and a sixth holding tank 102F.

At operation 552, the processor 302 of the controller 146 sends a signal 326G to a valve 112G coupling the etch bath 128 to the recycling system 138 to open the valve 112G. At operation 554, the processor 302 of the controller 146 sends a signal 328G to a pump 110G coupling the etch bath 128 to the recycling system 138 to transfer the desired amount 322 of the etchant solution 124 to the recycling system 138. In some embodiments, a portion or all of the etchant solution 124 that is held in the etch bath 128 may be transferred to the recycling system 138.

At operation 556, the processor 302 of the controller 146 sends a signal 330D to the recycling system 138 to recycle the transferred amount 322 of the etchant solution 124. In some embodiments, the recycling system 138 passes the transferred amount 322 of the etchant solution 124 through the one or more filters 140 to remove undissolved first nanoparticles 104 and/or undissolved second nanoparticles 106 from the transferred amount 322 of the etchant solution 124. The undissolved first nanoparticles 104 may be recovered from the one or more filters 140 and transferred to the first holding tank 102A. The undissolved second nanoparticles 106 may be recovered from the one or more filters 140 and transferred to the second holding tank 102B. The recycling system 138 recovers water 142 from the transferred amount 322 of the etchant solution 124 and holds the recovered water 142 in the fifth holding tank 102E. The recycling system 138 recovers an acid 144 from the transferred amount 322 of the etchant solution 124 and holds the recovered acid 144 in the sixth holding tank 102F.

At operation 558, the processor 302 of the controller 146 sends a signal 326H to a valve 112H coupling the fifth holding tank 102E to the third holding tank 102C to open the valve 112H. At operation 560, the processor 302 of the controller 146 sends a signal 328H to a pump 110H coupling the fifth holding tank 102E to the third holding tank 102C to transfer the recovered water 142 from the fifth holding tank 102E to the third holding tank 102C.

At operation 562, the processor 302 of the controller 146 sends a signal 326I to a valve 112I coupling the sixth holding tank 102F to the fourth holding tank 102D to open the valve 112I. At operation 564, the processor 302 of the controller 146 sends a signal 328I to a pump 110I coupling the sixth holding tank 102F to the fourth holding tank 102D to transfer the recovered acid 144 from the sixth holding tank 102F to the fourth holding tank 102D.

At operation 566, the processor 302 of the controller 146 determines a desired amount 324 of a new etchant solution 124 to be transferred from the second mixing tank 116B to the etch bath 128. At operation 568, the processor 302 of the controller 146 sends a signal 326F to the valve 112F coupling the second mixing tank 116B to the etch bath 128 to open the valve 112F. At operation 570, the processor 302 of the controller 146 sends a signal 328F to the pump 110F coupling the second mixing tank 116B to the etch bath 128 to transfer the desired amount 324 of the new etchant solution 124 from the second mixing tank 116B to the etch bath 128. In some embodiments, the desired amount 324 of the new etchant solution 124 may be determined such that the etch selectivity 320 of the resulting etchant solution 124 held by the etch bath 128 is within the desired etch selectivity range 316.

In response to determining at operation 548 that the etch selectivity 320 is within the desired etch selectivity range 316 or after performing operation 570, method 500 proceeds to operation 572. At operation 572, the processor 302 of the controller 146 determines whether all wafers 134 are processed. In response to determining at operation 572 that all wafers 134 are not processed, method 500 proceeds to operation 574. At operation 574, the processor 302 of the controller 146 sends a signal 330C to the transfer mechanism 148 to transfer a new wafer 134 from the loadlock chamber 136 into the etchant solution 124 of the etch bath 128. After performing operation 574, method 500 proceeds back to operation 540. In response to determining at operation 572 that all wafers 134 are processed, method 500 proceeds to end.

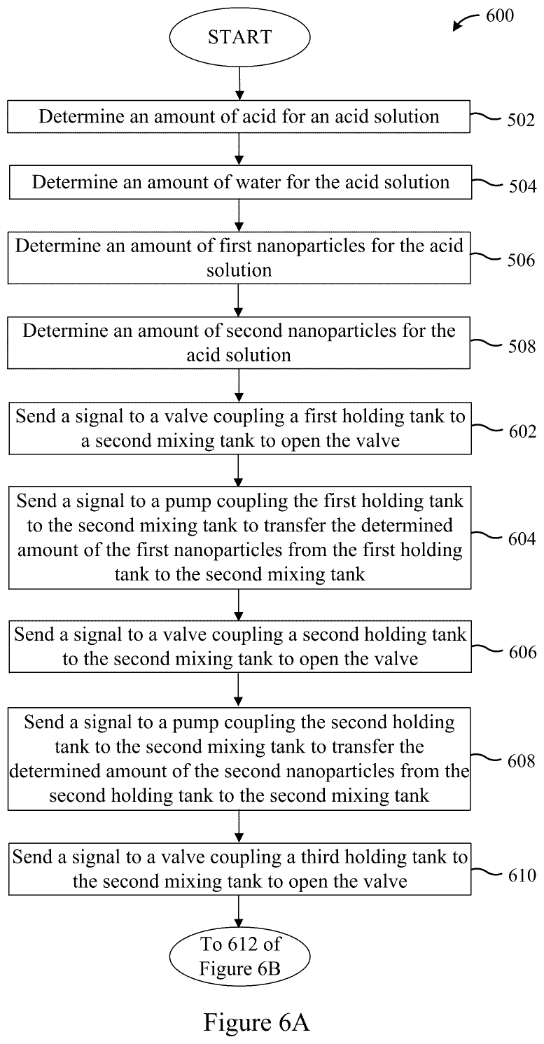

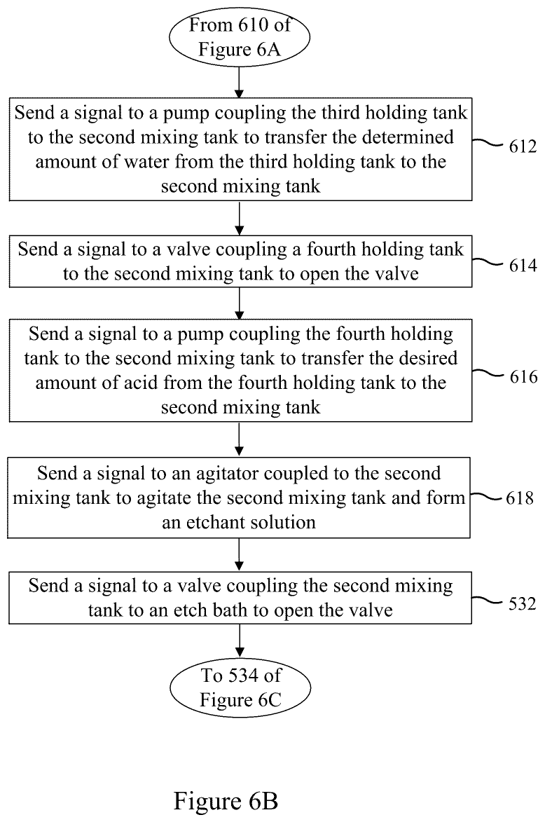

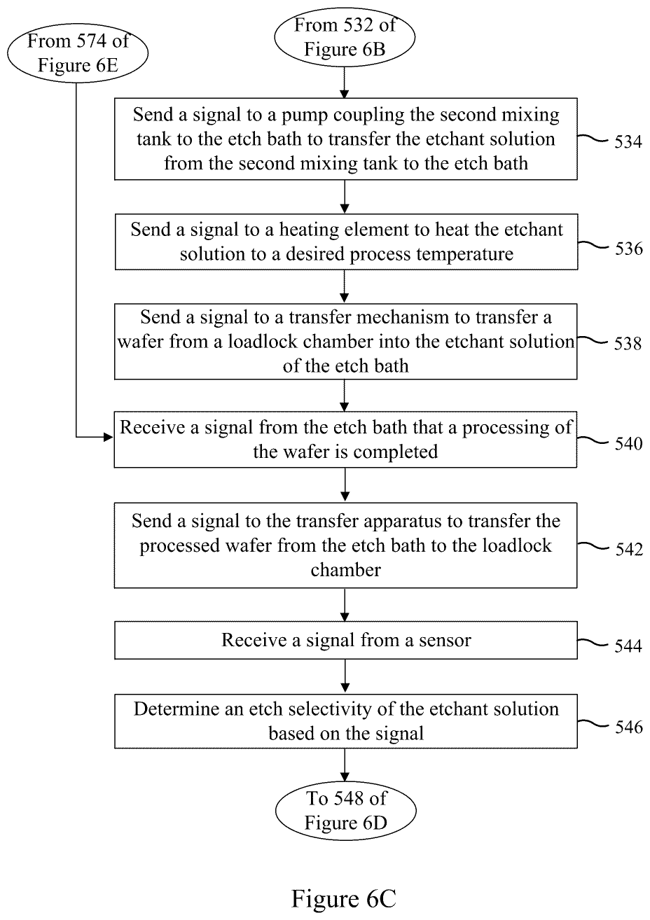

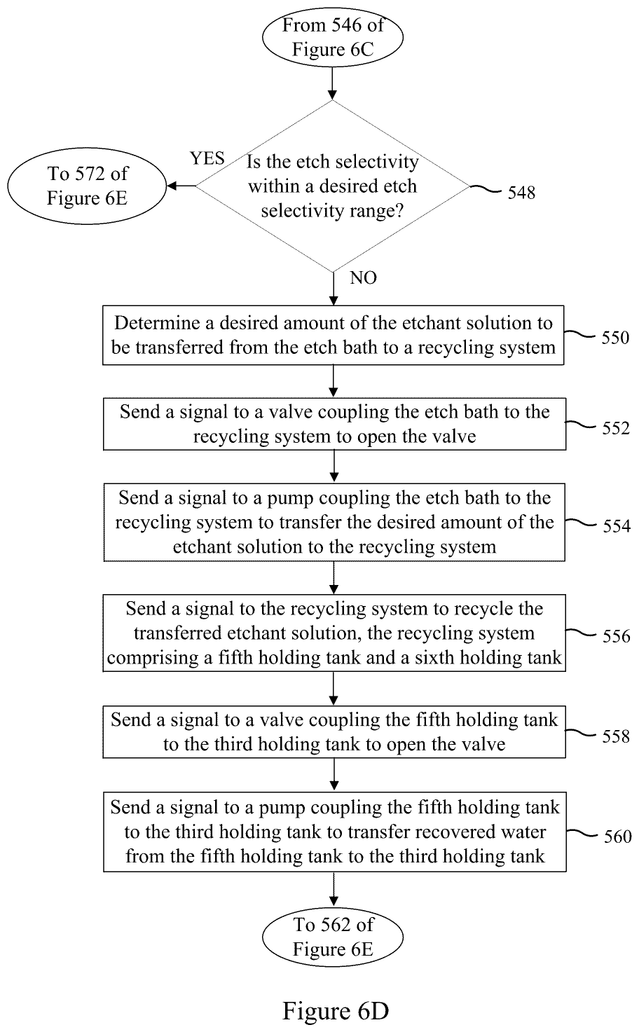

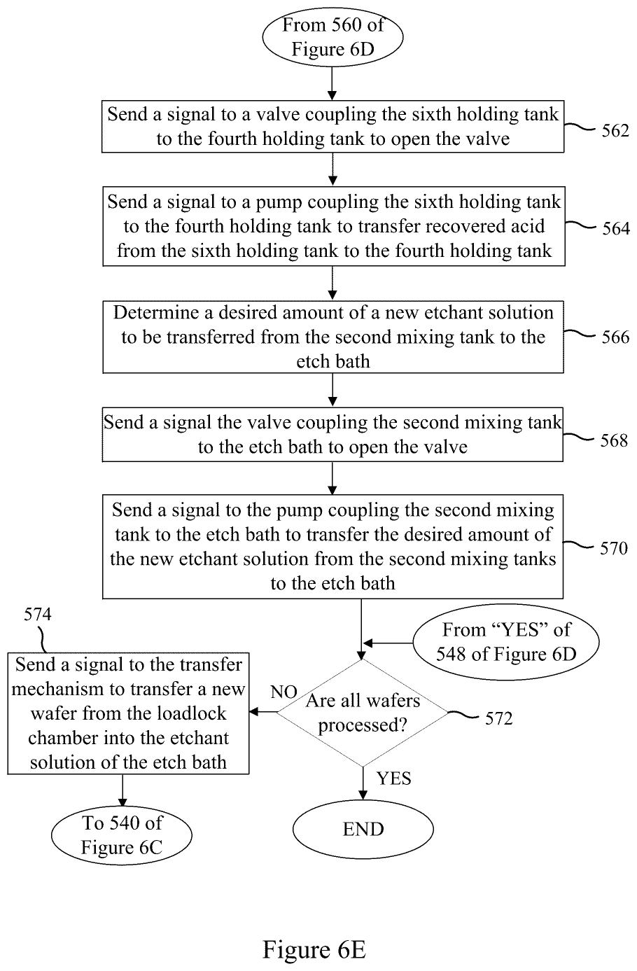

FIGS. 6A-6E illustrate a flow diagram of a method 600 for operating the etch apparatus 200 (see FIG. 2) in accordance with various embodiments. In some embodiments, operations of the etch apparatus 200 may be controlled by the controller 146 (see FIGS. 1 and 3). Method 600 is similar to method 500 (see FIGS. 5A-5E), similar operations being labeled by similar numerical references, and descriptions of the similar operations are not repeated herein.

In some embodiments, operations 502-508 of method 600 are performed as described above with reference to FIG. 5A and the description is not repeated herein. After performing operation 508, method proceeds to operation 602. At operation 602, the processor 302 of the controller 146 sends a signal 326A to a valve 112A coupling a first holding tank 102A to a second mixing tank 116B to open the valve 112A. At operation 604, the processor 302 of the controller 146 sends a signal 328A to a pump 110A coupling the first holding tank 102A to the second mixing tank 116B to transfer the determined amount 312 of the first nanoparticles 104 from the first holding tank 102A to the second mixing tank 116B.

At operation 606, the processor 302 of the controller 146 sends a signal 326B to a valve 112B coupling a second holding tank 102B to the second mixing tank 116B to open the valve 112B. At operation 608, the processor 302 of the controller 146 sends a signal 328B to a pump 110B coupling the second holding tank 102B to the second mixing tank 116B to transfer the determined amount 314 of the second nanoparticles 106 from the second holding tank 102B to the second mixing tank 116B.

At operation 610, the processor 302 of the controller 146 sends a signal 326C to a valve 112C coupling a third holding tank 102C to the second mixing tank 116B to open the valve 112C. At operation 612, the processor 302 of the controller 146 sends a signal 328C to a pump 110C coupling the third holding tank 102C to the second mixing tank 116A to transfer the determined amount 310 of water 108 from the third holding tank 102C to the second mixing tank 116A.

At operation 614, the processor 302 of the controller 146 sends a signal 326D to a valve 112D coupling a fourth holding tank 102D to the second mixing tank 116B to open the valve 112D. At operation 616, the processor 302 of the controller 146 sends a signal 328D to a pump 110D coupling the fourth holding tank 102D to the second mixing tank 116B to transfer the desired amount 308 of the acid 122 from the fourth holding tank 102D to the second mixing tank 116B. At operation 618, the processor 302 of the controller 146 sends a signal 330A to an agitator 120 coupled to the second mixing tank 116A to agitate the second mixing tank 116A and form an etchant solution. After performing operation 618, method 600 proceeds to operation 532. Operations 532-574 of method 600 are performed as described above with reference to FIGS. 5B-5E and the description is not repeated herein.

Example embodiments of the disclosure are described below. Other embodiments can also be understood from the entirety of the specification as well as the claims filed herein.

Example 1. An apparatus includes a first holding tank holding first nanoparticles, a second holding tank holding second nanoparticles, a third holding tank holding water, and a fourth holding tank holding an acid. The apparatus further includes a first mixing tank operably coupled to the first holding tank, the second holding tank, and the third holding tank. The first mixing tank mixes and holds a nanoparticle-water mixture of a portion of the water, a portion of the first nanoparticles, and a portion of the second nanoparticles. The apparatus further includes a second mixing tank operably coupled to the first mixing tank and the fourth holding tank. The second mixing tank mixes and holds an etchant solution including a mixture of a portion of the acid and the nanoparticle-water mixture. The apparatus further includes an etch bath operably coupled to the second mixing tank. The etch bath holds the etchant solution. The apparatus further includes a sensor operably coupled to the etch bath. The sensor monitors an etch selectivity of the etchant solution.

Example 2. The apparatus of example 1, further including a recycling system operably coupled to the etch bath, the third holding tank, and the fourth holding tank. The recycling system includes a filter configured to extract undissolved first nanoparticles and undissolved second nanoparticles from the etchant solution, a fifth holding tank holding water extracted from the etchant solution, and a sixth holding tank holding an acid extracted from the etchant solution.

Example 3. The apparatus of one of examples 1 and 2, further including an agitator operably coupled to the first mixing tank. The agitator maintains the portion of the first nanoparticles and the portion of the second nanoparticles in a state of suspension within the nanoparticle-water mixture.

Example 4. The apparatus of one of examples 1 to 3, where the first nanoparticles and the second nanoparticles comprise different materials.

Example 5. The apparatus of one of examples 1 to 4, further including a heating element operably coupled to the etch bath. The heating element adjusts a temperature of the etchant solution.

Example 6. The apparatus of one of examples 1 to 5, where the first nanoparticles include silicon nitride nanoparticles and the second nanoparticles include silicon oxide nanoparticles.

Example 7. The apparatus of one of examples 1 to 6, where the acid includes a phosphoric acid.

Example 8. A method includes adding first nanoparticles and second nanoparticles to water to form a nanoparticle-water mixture, agitating the nanoparticle-water mixture, adding the nanoparticle-water mixture to an acid to from an etchant solution, soaking a first wafer into the etchant solution, and monitoring an etch selectivity of the etchant solution. The method further includes, in response to determining that the etch selectivity of the etchant solution is outside a desired etch selectivity range, recycling at least a portion of the etchant solution.

Example 9. The method of example 8, where the first nanoparticles include silicon nitride nanoparticles and the second nanoparticles include silicon oxide nanoparticles.

Example 10. The method of one of examples 8 and 9, further including, in response to determining that the etch selectivity of the etchant solution is within the desired etch selectivity range, soaking a second wafer into the etchant solution.

Example 11. The method of one of examples 8 to 10, further including setting a temperature of the etchant solution to a desired temperature.

Example 12. The method of one of examples 8 to 11, where the desired temperature is in a range from 100° C. to 165° C.

Example 13. The method of one of examples 8 to 12, where the acid includes a phosphoric acid.

Example 14. The method of one of examples 8 to 13, where recycling the portion of the etchant solution includes filtering the portion of the etchant solution to remove undissolved first nanoparticles and undissolved second nanoparticles, extracting water from the portion of the etchant solution, and extracting an acid from the portion of the etchant solution.

Example 15. A method includes adding silicon oxide nanoparticles and silicon nitride nanoparticles to water to form a nanoparticle-water mixture, agitating the nanoparticle-water mixture to maintain the silicon oxide nanoparticles and the silicon nitride nanoparticles in a state of suspension within the nanoparticle-water mixture, adding the nanoparticle-water mixture to phosphoric acid to from an etchant solution, and soaking a first wafer into the etchant solution. The first wafer includes one or more silicon oxide features and one or more silicon nitride features. The method further includes monitoring an etch selectivity of the etchant solution and, in response to determining that the etch selectivity of the etchant solution is outside a desired etch selectivity range, recycling at least a portion of the etchant solution.

Example 16. The method of example 15, further including, in response to determining that the etch selectivity of the etchant solution is within the desired etch selectivity range, soaking a second wafer into the etchant solution.

Example 17. The method of one of examples 15 and 16, further including setting a temperature of the etchant solution to a desired temperature.

Example 18. The method of one of examples 15 to 17, where the desired temperature is in a range from 100° C. to 165° C.

Example 19. The method of one of examples 15 to 18, where recycling the portion of the etchant solution includes filtering the portion of the etchant solution to remove undissolved silicon nitride nanoparticles and undissolved silicon oxide nanoparticles, extracting water from the portion of the etchant solution, and extracting phosphoric acid from the portion of the etchant solution.

Example 20. The method of one of examples 15 to 19, where the desired etch selectivity range is 80:1 or greater.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. An apparatus comprising:
a first holding tank holding first nanoparticles;
a second holding tank holding second nanoparticles;
a third holding tank holding water;
a fourth holding tank holding an acid;
a first mixing tank operably coupled to the first holding tank, the second holding tank, and the third holding tank, wherein the first mixing tank mixes and holds a nanoparticle-water mixture of a portion of the water, a portion of the first nanoparticles, and a portion of the second nanoparticles;
a second mixing tank operably coupled to the first mixing tank and the fourth holding tank, wherein the second mixing tank mixes and holds an etchant solution comprising a mixture of a portion of the acid and the nanoparticle-water mixture;
an etch bath operably coupled to the second mixing tank, wherein the etch bath holds the etchant solution; and
a sensor operably coupled to the etch bath, wherein the sensor monitors an etch selectivity of the etchant solution.

2. The apparatus of claim 1, further comprising a recycling system operably coupled to the etch bath, the third holding tank, and the fourth holding tank, wherein the recycling system comprises:
a filter configured to extract undissolved first nanoparticles and undissolved second nanoparticles from the etchant solution;
a fifth holding tank holding water extracted from the etchant solution; and
a sixth holding tank holding an acid extracted from the etchant solution.

3. The apparatus of claim 1, further comprising an agitator operably coupled to the first mixing tank, wherein the agitator maintains the portion of the first nanoparticles and the portion of the second nanoparticles in a state of suspension within the nanoparticle-water mixture.

4. The apparatus of claim 1, wherein the first nanoparticles and the second nanoparticles comprise different materials.

5. The apparatus of claim 1, further comprising a heating element operably coupled to the etch bath, wherein the heating element adjusts a temperature of the etchant solution.

6. The apparatus of claim 1, wherein the first nanoparticles comprise silicon nitride nanoparticles and the second nanoparticles comprise silicon oxide nanoparticles.

7. The apparatus of claim 1, wherein the acid comprises a phosphoric acid.

8. A method comprising:
adding first nanoparticles and second nanoparticles to water to form a nanoparticle-water mixture;
agitating the nanoparticle-water mixture;
adding the nanoparticle-water mixture to an acid to from an etchant solution;
soaking a first wafer into the etchant solution;
monitoring an etch selectivity of the etchant solution; and
in response to determining that the etch selectivity of the etchant solution is outside a desired etch selectivity range, recycling at least a portion of the etchant solution.

9. The method of claim 8, wherein the first nanoparticles comprise silicon nitride nanoparticles and the second nanoparticles comprise silicon oxide nanoparticles.

10. The method of claim 8, further comprising, in response to determining that the etch selectivity of the etchant solution is within the desired etch selectivity range, soaking a second wafer into the etchant solution.

11. The method of claim 8, further comprising setting a temperature of the etchant solution to a desired temperature.

12. The method of claim 11, wherein the desired temperature is in a range from 100° C. to 165° C.

13. The method of claim 8, wherein the acid comprises a phosphoric acid.

14. The method of claim 8, wherein recycling the portion of the etchant solution comprises:
filtering the portion of the etchant solution to remove undissolved first nanoparticles and undissolved second nanoparticles;
extracting water from the portion of the etchant solution; and
extracting an acid from the portion of the etchant solution.

15. A method comprising:
adding silicon oxide nanoparticles and silicon nitride nanoparticles to water to form a nanoparticle-water mixture;
agitating the nanoparticle-water mixture to maintain the silicon oxide nanoparticles and the silicon nitride nanoparticles in a state of suspension within the nanoparticle-water mixture;
adding the nanoparticle-water mixture to phosphoric acid to from an etchant solution;
soaking a first wafer into the etchant solution, wherein the first wafer comprises one or more silicon oxide features and one or more silicon nitride features;
monitoring an etch selectivity of the etchant solution; and
in response to determining that the etch selectivity of the etchant solution is outside a desired etch selectivity range, recycling at least a portion of the etchant solution.

16. The method of claim 15, further comprising, in response to determining that the etch selectivity of the etchant solution is within the desired etch selectivity range, soaking a second wafer into the etchant solution.

17. The method of claim 15, further comprising setting a temperature of the etchant solution to a desired temperature.

18. The method of claim 17, wherein the desired temperature is in a range from 100° C. to 165° C.

19. The method of claim 15, wherein recycling the portion of the etchant solution comprises:
filtering the portion of the etchant solution to remove undissolved silicon nitride nanoparticles and undissolved silicon oxide nanoparticles;
extracting water from the portion of the etchant solution; and
extracting phosphoric acid from the portion of the etchant solution.

20. The method of claim 15, wherein the desired etch selectivity range is 80:1 or greater.
